(19) United States
(12) Patent Application Publication
(10) Pub. No.: US 2008/0298148 A1
(43) Pub. Date: Dec. 4, 2008

(54) Semiconductor memory device and test method therefor

(75) Inventor: Shunya Nagata, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/155,240

(22) Filed: May 30, 2008

(30) Foreign Application Priority Data
Jun. 1, 2007 (JP) 2007-146875

(51) Int. Cl. G11C 29/00

(52) U.S. Cl. 365/201

(57) ABSTRACT

There is disclosed a semiconductor memory device in which, activation timing control of a plurality of word lines of a plurality of ports is managed based on a plurality of clock signals, test signals are provided in association with the plurality of clock signals respectively controlling the activation timings of the word lines of the plurality of ports. If, with the cell, with the plurality of ports selected, the one test signal is in an activated state and the other test signal is in a non-activated state, activation of word lines of the plurality of ports is controlled in response to one clock signal, with the other clock signal being then masked. The timing difference, inclusive of the zero timing difference, between the activation timing of the plurality of word lines of the plurality of port may be finely adjusted by a delay control signal.

### REFERENCE TO RELATED APPLICATION

This application is based upon and claims the benefit of the priority of Japanese patent application No. 2007-146875, filed on Jun. 1, 2007, the disclosure of which is incorporated herein in its entirety by reference thereto.

### FIELD OF THE INVENTION

This invention relates to a semiconductor memory device. More particularly, the invention relates to a semiconductor memory device adapted for testing of a cell having a plurality of ports, and to a method of testing a semiconductor memory device.

### BACKGROUND OF THE INVENTION

FIG. 12 is a diagram illustrating the configuration of a SRAM (Static Random-Access Memory) cell of a dual-port static memory circuit in which each cell is composed of eight transistors. As shown in FIG. 12, the memory cell includes a PMOS transistor Q2 (a load) and an NMOS transistor Q1 (a driver transistor) connected in series between a first power supply VDD and a second power supply VSS, and a PMOS transistor Q4 (a load) and an NMOS transistor Q3 (a driver transistor) connected in series between the power supplies VDD and VSS. Commonly coupled drains (N1) of the PMOS transistor Q2 and NMOS transistor Q1 are connected to commonly coupled gates of the PMOS transistor Q4 and NMOS transistor Q3, and commonly coupled drains (N2) of the PMOS transistor Q4 and NMOS transistor Q3 are connected to commonly coupled gates of the PMOS transistor Q2 and NMOS transistor Q1. Provided between the node N1 and bit lines DTA and DTB are A-port and B-port access transistors Q5 and Q6 whose gates are connected to word lines WLA and WLB, respectively, and provided between the node N2 and complementary bit lines DBA and DBB are A-port and B-port access transistors Q7 and Q8 whose gates are connected to the word lines WLA and WLB, respectively.

In the dual-port static memory circuit having the SRAM cell illustrated in FIG. 12, each of the ports A and B is used as an I/O port where reading and writing are performed (in which case the two ports are capable of simultaneous READ). The port A may be used as a write-only port and the port B may be used as a read-only port (or vice versa). With regard to a multiport memory circuit, refer also to the description in Patent Document 1.

[Patent Document 1] Japanese Patent Kokai Publication No. JP-A-1-296486

### SUMMARY OF THE DISCLOSURE

The following analysis is given by the present invention. The disclosures of the above-mentioned Patent Document are herein incorporated by reference thereto, and regarded as part of the disclosure of the present invention.

The problem with the dual-port static memory circuit having the SRAM cell shown in FIG. 12 is that the memory cannot be tested in the worst case with regard to operating margin. This will now be described. It should be noted that the description that follows is based upon the results of analysis conducted by the Inventor.

In FIG. 12, there is illustrated an example of operation of the SRAM cell in a case where the ports A and B are read simultaneously, in which currents Icell_A and Icell_B flow simultaneously from the bit lines DTA and DTB to the driver transistor Q1 within the SRAM cell. In a case where the same row is accessed by the ports A and B simultaneously, the word lines WLA and WLB of both ports A and B go HIGH simultaneously. Hence, port A access transistors Q5 and Q7 and port-B access transistors Q6 and Q8 turn on simultaneously. It should be noted that in the configuration shown in FIG. 12, it is assumed that the bit-line pairs (DTA, DBA) and (DTB, DBB) of both ports were pre-charged to the HIGH level before activation of the select word line.

Since the driver transistor Q1 in the SRAM cell have to pull-down both bit lines DTA and DTB of ports A and B to the LOW level, the pull-down characteristic of bit lines DTA and DTB is deteriorated in comparison with a case where the bit line of one port is pulled down to the LOW level. Consequently, the value of bit-line difference potential [ΔVBL: difference potential between bit-line pair (DTA, DBA) and between bit-line pair (DTB, DBB)] read by a sense amplifier (not shown) is reduced so that operating margin decreases and minimum operating voltage worsens.

The longer becomes a period of time in which the ON states of the port A and port-B access transistors Q5 and Q6 overlap, the greater becomes the extent of the decline in the value of the bit-line difference potential ΔVBL. Accordingly, the time at which the potentials at the word lines of both ports rise simultaneously is the point at which the cell-data read margin is most severe and the minimum operating voltage is at its worst value.

FIG. 13A is a graph illustrating the relationship between a difference Δt[=t(WLA−WLB)] between rise timings of the word lines WLA and WLB of the ports A and B and the bit-line difference potential ΔVBL (V|DTA−DBA|, V|DTB−DBB|). It will be appreciated that in a case where the rise timings of the word lines WLA and WLB of the ports A and B overlap (see FIG. 5C), ΔVBL is minimum (see the valley of ΔVBL in FIG. 13A).

Specifically, when one bit line of the bit-line pairs is HIGH based upon the cell data, the driver transistor of the SRAM cell discharges the other bit line of the bit-line pairs to the LOW level. However, in a case where the other bit lines (e.g., DTA, DTB) of the bit line pairs of ports A and B are pulled down to LOW simultaneously by one driver transistor, the potential difference between the bit-line pairs diminishes and the speed of enlarging the potential difference becomes slow, as illustrated in FIG. 13C, in comparison with a case where just the bit line of one port is pulled down to the LOW level, from the standpoint of the current driving capability of the driver transistor. By contrast, if the timings at which the word lines WLA and WLB of ports A and B are activated (namely the rise timings) are shifted forward or backward in terms of time, the bit-line difference potential ΔVBL is large (see FIG. 13B).

A test of a memory device conducted prior to shipment thereof, should employ worst case testing in which the bit-line difference potential ΔVBL is minimum.

However, for the following two reasons, a case occurs where the word lines of both ports cannot be driven at the same timing and the operating margin does not exhibit its worst value:

(a) owing to variations between elements in a chip, skew (a shift in timing) occurs between ports in the path from a BIST (Build-In Self-Test) apparatus to the memory; and

(b) skew of an internal clock for activating a word line, ascribable to the physical layout in the memory, occurs. This will be described below in further detail with reference to the drawings.

FIG. 14 illustrates a typical example of the configuration of a word-line control unit in a static memory circuit having the SRAM cell shown in FIG. 12. Shown in FIG. 14 is an example of the configuration of a clock-synchronized dual-port static memory circuit in which word-line activation timing is controlled based upon an input clock signal.

With reference to FIG. 14, clock signals CLKA and CLKB supplied to clock terminals (A) and (B), respectively, are received by buffers 101 and 102, respectively, and internal clock signals ICLA and ICLB are output from the buffers 101 and 102, respectively.

XKA and XEA of address selection signals (A) (row address) that select word line WLA of port A are outputs of a main pre-decoder (not shown) and a sub pre-decoder (not shown) of an X-address decoder (row-address decoder) for port A, respectively.

XKB and XEB of address selection signals (B) (row address) that select word line WLB of port B are outputs of a main pre-decoder (not shown) and a sub pre-decoder (not shown) of an X-address decoder (row-address decoder) for port B, respectively.

There are provided a NAND gate 103 that receives XKA and XEA of the address selection signal (A), and a CMOS transfer gate 105 comprising a PMOS transistor having a gate at which the output of the NAND gate 103 is received, and an NMOS transistor having a gate that receives a signal that is the result of inverting the output of the NAND gate 103 by an inverter 104. When XKA and XEA are both HIGH, the output of the NAND gate 103 is LOW. As a result, the CMOS transfer gate 105 turns on and transfers the internal clock signal ICLA, and the word line WLA is raised to the high potential by an inverter 107 and an inverting buffer (inverting-type word driver) 108. In a case where XKA and XEA are both other than HIGH (i.e., in a case where either one is LOW), the output of the NAND gate 103 goes HIGH, an NMOS transistor 106 turns on, the input to the inverter 107 is fixed at the LOW level and the word line WLA is set to the LOW level. The period of time during which the select word line is activated corresponds to the duration of the HIGH pulse of the internal clock signal ICLA. The configuration is similar with regard to the address selection signal (B) of port B.

FIG. 15 is a diagram schematically illustrating a test of a static memory circuit by BIST. In FIG. 15, 10A and 10B each include a write amplifier (not shown) and a sense amplifier (not shown) for respectively writing and reading data of port A and port B of a SRAM cell array (SRAM CELL). Control units CNTA and CNTB receive clock signals CLKA and CLKB and perform timing control of selected word lines of port A and port B, respectively. WLDA and WLDB include X-address decoders for decoding row addresses of port A and port B, respectively and word drivers for driving select word lines of port A and port B, respectively. When the test is conducted, clock signals from a BIST circuit 202 are distributed via clock distribution paths (clock buffer groups 203 and 204) and arrive at respective clock terminals CLKA and CLKB of port A and port B of a memory circuit 201.

In this case, a clock skew is generated between the ports A and B owing to parameter variations betweens the BIST circuit 202 and memory circuit 201.

Further, a skew between the internal clocks of the two ports is generated owing to the physical layout within the memory circuit 201. For example, since the path of the clock from the clock terminal CLKA to the word line WLA has a path length different from the path of the clock from the clock terminal CLKB to the word line WLB, a skew is generated between the internal clocks ICLA and ICLB.

For these reasons, it is difficult to realize a test in which the word line WLA of the port A and the word line WLB of the port B are made to rise simultaneously.

Further, even in a case where a memory device is tested using not a BIST circuit but test by a tester that has a skew between pins calibrated, similar problems arise owing to a skew between the internal clocks of the two ports ascribable to the physical layout within the memory circuit and a skew between clock terminals of the ports A and B of the memory circuit 201 within the semiconductor device.

In a memory device provided with a cell including a plurality of ports in accordance with the related art, it is difficult to exercise control so as to cause word lines of a plurality of ports to rise simultaneously when the device is tested, as set forth above. This means that the device cannot be tested in the worst state. As a result, pass/fail decision accuracy (measurement precision) is limited, and this leads to a limitation on an improvement in product yield and reliability.

In addition, the timing of activation of the word lines of the plurality of ports is affected by the skew, so that it is not possible to make fine adjustment of activation timing difference of the word lines of the plurality of ports.

The invention disclosed in this application has the following configuration. It should be noted that what is indicated by the reference characters within the parentheses in the following description represent examples in order to clarify the present invention and should not be interpreted as limiting the present invention.

According to a first aspect of the present invention, there is provided a semiconductor memory device comprising: a memory cell connected to a plurality of word lines corresponding respectively to a plurality of ports; a plurality of test control signals associated respectively with a plurality of the timing signals which are for controlling the activation timings of word lines of the plurality of ports; and a control circuit that with regard to the memory cell with the plurality of ports thereof being selected, when one of the plurality of test control signals respectively associated with the plurality of ports selected, is in an activated state, and the remaining test control signals are in a non-activated state, exercises control so as to mask the timing signals associated with the non-activated test control signals; and in response to the sole timing signal associated with said test control signal in the activated state, activates the word lines of the plurality of ports selected. The control circuit variably controls the activation timing of the word lines of the plurality of ports activated in response to said sole timing signal based on the delay control signal.

In another aspect of the present invention, there is provided a semiconductor memory device comprising:

a memory cell connected to respective word lines of at least a first port and a second port:

first and second test control signals, associated with first and second clock signals used for controlling activation timings of the word lines of the first and second ports;

a first control circuit which, if, for a cell for which the first and second ports are selected, the first test control signal is in an activated state and the second test control signal is in a non-activated state, masks the second clock signal, and which, in response to the first clock signal, exercises control to activate the word lines of the first and second ports, wherein the first control circuit in activating the word lines of the first and second ports in response to the first clock signal variably adjusts the activation timing of the word lines of the first and second ports based on a delay control signal received; and

a second control circuit which, if the second test control signal is in an activated state and the first test control signal is in a non-activated state, masks the first clock signal, and which, in response to the second clock signal, exercises control to activate the word lines of the first and second ports, wherein the second control circuit in activating the word lines of the first and second ports in response to the second clock signal variably adjusts the activation timing of the word lines of the first and second ports based on the delay control signal.

According to the present invention, if, with a cell for which the first and second ports are selected, the first and second test control signals are both in a non-activated state, activation of the word lines of the first port and activation of the word lines of second port are exercised independently of each other based on the first and second clock signals.

The semiconductor memory device may further include a first circuit (11, 12) for receiving the first clock signal (CLKA) and the second test control signal (TESTB). The first circuit outputs the first clock signal as a first internal clock signal (ICLA) in case the second test control signal (TESTB) is in an inactivated state, while the first circuit (11,12) not transferring the first clock signal, and fixing the first internal clock signal in a non-activated state in case the second test control signal (TESTB) is in an activated state. The semiconductor memory device may further include a second circuit (13, 14) for receiving the second clock signal (CLKB) and the first test control signal (TESTA). The second circuit (13,14) outputs the second clock signal as a second internal clock signal (ICLB)in case the first control signal (TESTA) is in a non-activated state, while the second circuit not transferring the second clock signal, and fixing the second internal clock signal in a non-activated state in case the first test control signal is in an activated state. The semiconductor memory device may further include a first switch (transfer gate 17) for receiving the first internal clock signal (ICLA) from the first circuit (11, 12) with the first switch being turned on to transfer and output the first internal clock signal when the address selection signal of the first port (XKA, XKE) indicates a selected state. The semiconductor memory device may further include a second switch (24) for receiving the second internal clock signal (ICLB) from the second circuit (13, 14), with the second switch being turned on to transfer and output the second internal clock signal when the address selection signal (XKB, XKE) of the second port indicates a selected state. The semiconductor memory device may further include first and third variable delay circuits (30, 32) for receiving an output signal from the first switch (17) in common, and second and fourth variable delay circuits (31, 33) for receiving an output signal from the second switch (24) in common. The semiconductor memory device may further include a first logic circuit (19) for receiving the second test control signal (TESTB) and a signal which is an output of the second switch (transfer gate 24) delayed by the third variable delay circuit (32), with the first logic circuit (19) outputting a signal in a non-activated state when one or both of inputs are in a non-activated state a signal in an activated state when both of inputs are in an activated state. The semiconductor memory device may further include a second logic circuit (20) for receiving an output signal of the first logic circuit (19) and a signal which is an output of the first switch (17) delayed by the first variable delay circuit (30), with the second logic circuit (20) outputting one of inputs when the other input is in a non-activated state. The semiconductor memory device may further include a first word driver (21) for receiving the output signal of the second logic circuit (20) to drive the word lines of the first port, and a third logic circuit (26) for receiving the first test control signal (TESTA) and a signal which is the output signal of the first switch (17) delayed by the fourth variable delay circuit (33). The third logic circuit (26) outputs a signal in a non-activated state if one or both of inputs are in a non-activated state, while outputting a signal in an activated state if both inputs are in an activated state. The semiconductor memory device may further include a fourth logic circuit (27) for receiving an output signal of the third logic circuit (26) and a signal which is an output signal of the second switch (24) delayed by the third variable delay circuit (32), with the fourth logic circuit (27) outputting one of inputs if the other input is in a non-activated state. The semiconductor memory device may further include a second word driver (28) for receiving an output signal of the fourth logic circuit to drive the word lines of the second port.

According to the present invention, the first and third logic circuits may each be a logical product (AND) circuit while the second and fourth logic circuits may each be an negative logical sum (NOR) circuit. The first and second word drivers may each be an inverting driver.

According to the present invention, the cell may be a static cell including two inverters (Q1, Q2), (Q3, Q4) having inputs and outputs cross-coupled at a first node (N1 of FIG. 12) and at a second node (N2 of FIG. 12), first and second access transistors (Q5, Q6) connected between the first node (N1) and bit lines (DTA, DTB) of the first and second ports and having control terminals connected to the word lines of the first and second ports, and third and fourth access transistors (Q7, Q8) connected between the second node (N2) and complementary bit lines (DBA, DBB) of the first and second ports and having control terminals connected to the word lines of the first and second ports.

In the above first aspect of the present invention, an input clock signal is used as the timing signal, and the word line selected is activated in response to the clovk signal.

If, in activating the word lines on the same row, the test control signal of one of the first and second ports is activated, the word line of the other port is driven at the same or different timing in response to the activation timing of the word line of the one port.

In yet another aspect, the present invention provides a testing method of a semiconductor memory device including a memory cell connected to at least a word line of a first port and a word line of a second port, said method comprising:

providing first and second test control signals, in association with first and second clock signals used respectively for controlling activation timings of the word lines of the first and second ports;

with regard to a memory cell with the first and second ports thereof being selected, masking the second clock signal if the first test control signal is in an activated state and the second test control signal is in a non-activated state, and activating the word lines of the first and second ports at the same timing or different timings, in accordance with a value as set based on a delay control signal received, in response to the first clock signal, to read cell data from bit lines of the first and second ports; and

masking the first clock signal if the second test control signal is in an activated state and the first test control signal is in a non-activated state, and activating the word lines of the first and second ports at the same timing or different timings, in accordance with a value as set based on a delay control signal, in response to the second clock signal, to read cell data from bit lines of the first and second ports.

According to the present invention, the timing of activation of word lines of different ports may be finely adjusted for a cell for which a plurality of ports are selected. It is possible in this manner to conduct a worst-case testing in e.g. a margin test, as well as to improve test accuracy and contribute to improved product yield and reliability.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a diagram showing the configuration of an exemplary embodiment of the invention;

FIG. 2 is a diagram showing the configuration of an example of a delay decoder of the exemplary embodiment of the invention;

FIG. 3 is a diagram showing the configuration of another example of a delay decoder of the exemplary embodiment of the invention;

FIG. 4A is a diagram showing an illustrative configuration of a variable delay circuit (Delay Box1) of an exemplary embodiment of the present invention;

FIG. 4B is a diagram showing an illustrative configuration of a variable delay circuit (Delay Box2) of an exemplary embodiment of the present invention;

FIG. 5A is a diagram showing an illustrative configuration of a variable delay circuit (Delay Box1) of an exemplary embodiment of the present invention;

FIG. 5B is a diagram showing an illustrative configuration of a variable delay circuit (Delay Box2) of another exemplary embodiment of the present invention;

FIG. 6 is a diagram showing, in a list form, the relationship among the delay values of the variable delay circuits (Delay Box1 and Delay Box2) according to an exemplary embodiment of the present invention, signals DLY0 to DLY2, signals D0 to D6, modes and remarks (explanation of the operations);

FIG. 7 is a diagram showing, in a list form, the relationship among the delay values of the variable delay circuits (Delay Box1 and Delay Box2) according to another exemplary embodiment of the present invention, signals DLY0 to DLY2, signals D0 to D6, modes and remarks (explanation of the operations);

FIG. 8 is a timing chart for illustrating the operation of an exemplary embodiment of the present invention;

FIG. 9A is a flowchart for illustrating the test sequence of the present invention in case delay control is exercised on the BIST side.

FIG. 9B is a flowchart for illustrating the test sequence of the present invention in case delay control is exercised on the user side;

FIG. 10 is a schematic view for illustrating the test in an exemplary embodiment of the present invention;

FIG. 11 is a schematic view for illustrating the test in another exemplary embodiment of the present invention;

FIG. 12 is a schematic view for illustrating simultaneous READ in an SRAM cell;

FIG. 13 is a schematic view for illustrating problems met in simultaneous READ in an SRAM cell;

FIG. 14 is a diagram showing the configuration of a word line control circuit of a dual-port clock synchronized static memory;

FIG. 15 is a schematic view for illustrating the testing of a dual-port clock synchronized static memory; and FIG. 16 is a diagram showing the configuration of exemplary embodiment of the present invention.

### PREFEERED MODES OF THE PRESENT INVENTION

A semiconductor memory device according to the present invention includes a cell having a plurality of ports. A plurality of test control signals (TESTA and TESTB) are provided in correspondence with a plurality of timing signals (e.g., clock signals CLKA and CLKB) for controlling respective ones of activation timings of word lines of the plurality of ports. With regard to the cell with the plurality of ports being selected, when one test control signal among the plurality of test control signals corresponding to respective ones of the selected plurality of ports is in an activated state (enabled) and the remaining test control signals are in a deactivated state (disabled), control is exercised so as to mask the timing signals corresponding to the test control signals in the deactivated state and, in response to the one timing signal corresponding to the one test control signal in the activated state, activate the word lines (e.g., WLA and WLB) of the selected plurality of ports.

According to the present invention, a delay control signal is introduced to make fine adjustment of the timing difference (delay) between the activation timings of the word line corresponding to one of the ports and that of the word line corresponding to the other port at the time of activation of the test control signal. According to the present invention, this fine delay adjustment may be made from the BIST in the semiconductor device or from the user logic side.

If, in a case where the present invention is applied to a dual-port clock-synchronized static memory circuit in which each port functions as an I/O port, the test control signal for one port of the first and second ports is in the activated state (enabled) in the activation of word lines in the same row, then the activation (rise) of the word line of the other port also is controlled to occur at the same timing as that of the word line of the one port or with a variably adjustable timing difference.

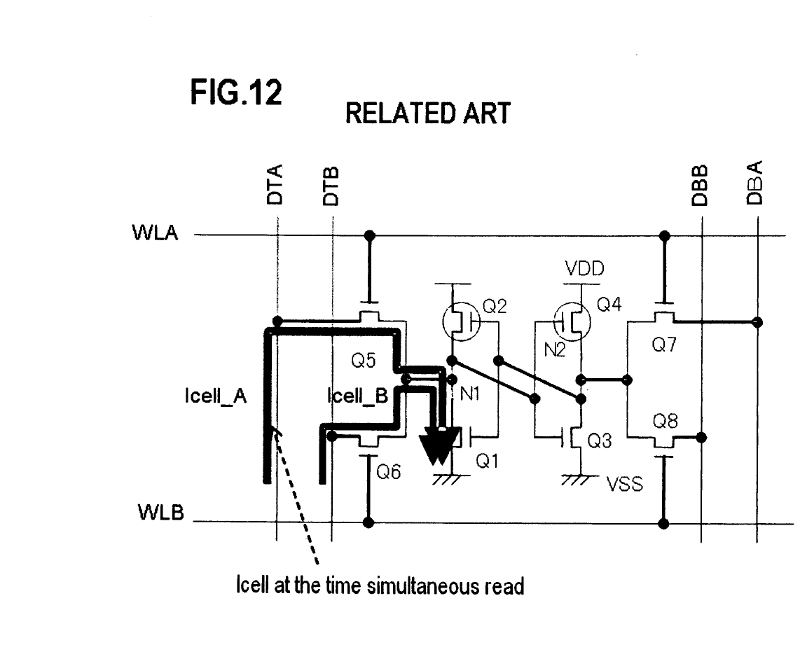

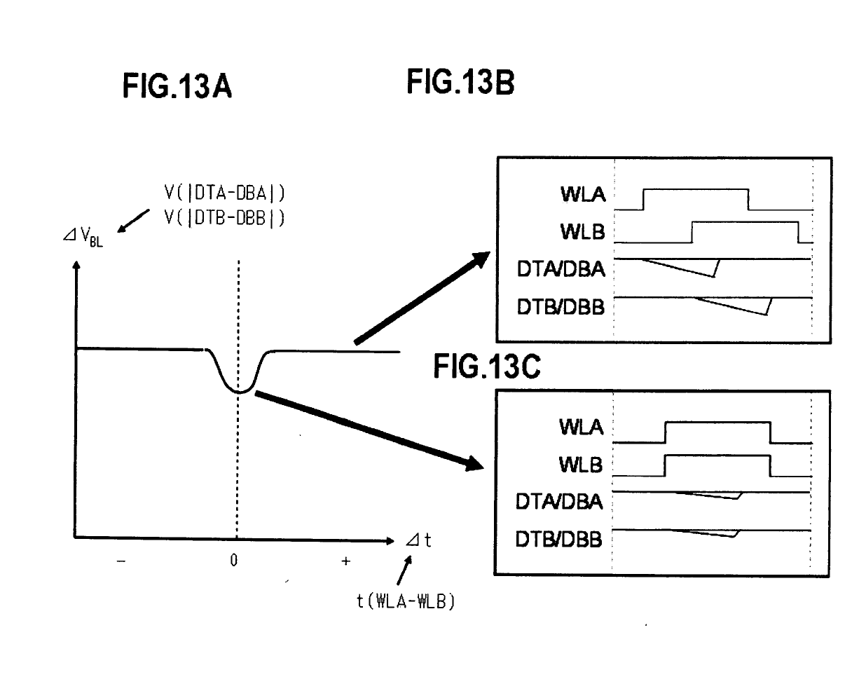

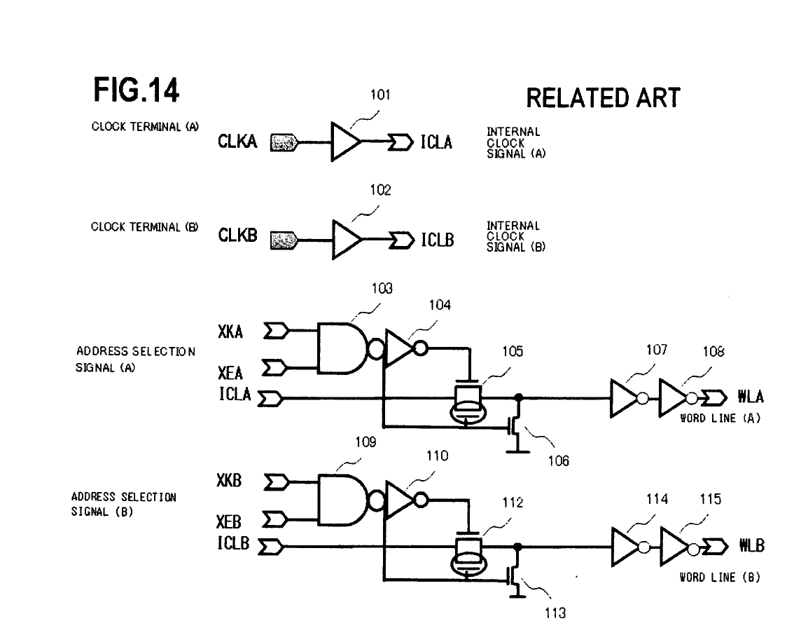

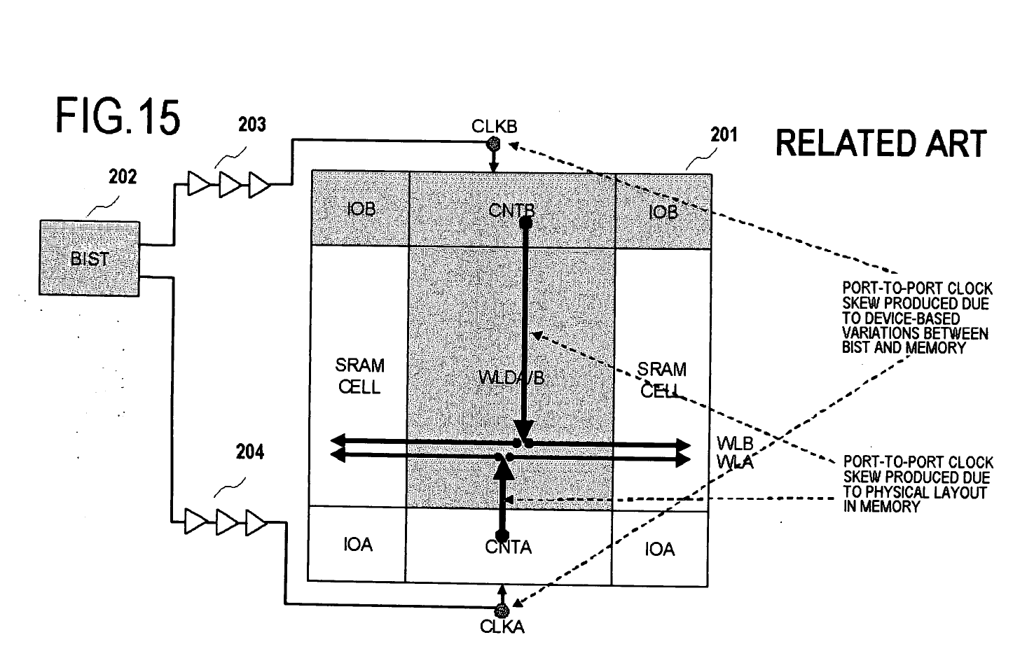

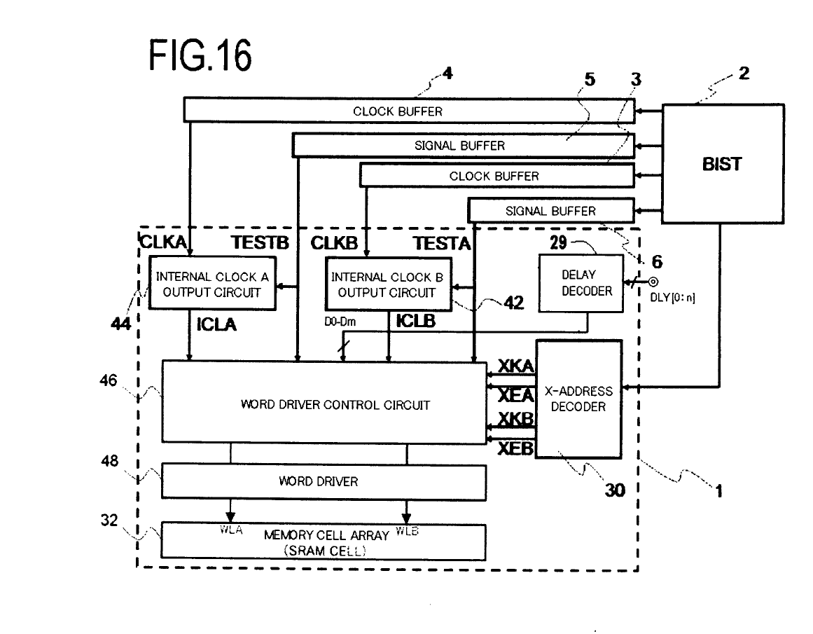

According to the present invention, if the test control signal of one of the ports is activated (enabled), the internal clock of the other port is controlled to be deactivated, thereby enabling a timing margin test, including the worst condition for the operational timing margin, at the time of memory testing by BIST, for instance. In simultaneously accessing plural ports on the same row, the data read margin is smallest when the word lines of the ports A and B are activated simultaneously. At this time, the minimum power supply voltage constitutes a worst case. By driving the word lines of the ports A and B in common with the clock of the port A at the same timing, and by making fine adjustment of the word line activation timing of the ports A and B, the worst condition may be achieved, without taking into account the clock skew between the two ports from the BIST to the memory or the internal clock skew ascribable to the physical layout in the memory. Further, according to the present invention, the marginal test with variable word line activation timing differences may be improved in accuracy. In an example, as now described, the memory cell is a dual-port SRAM cell, shown in FIG. 12, and the timing difference is variably introduced in the word line activation of the ports A and B. In the following example, the present invention is applied to a clock-synchronized static memory cell circuit in which word line activation is controlled based on a clock signal.

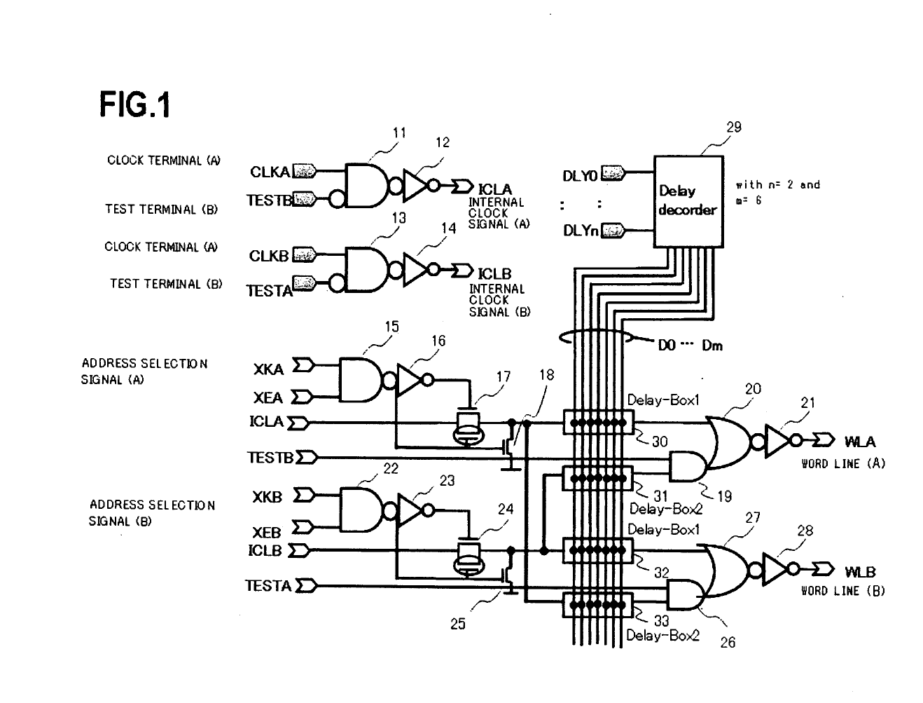

FIG. 1 is a diagram showing the configuration of a circuit for controlling the word line activation according to an example of the present invention (an X-address decoder and a word driver).

Referring to FIG. 1, the circuit includes a two-input NAND circuit 11 which has first and second inputs connected to a clock terminal (A) to which a clock signal CLKA is supplied, and a terminal for TEST for the port B (TESTB), respectively, and an inverting buffer 12 that receives an output of the NAND circuit 11. The inverting buffer 12 outputs an internal clock ICLA.

The operation of this circuit portion is now described. When a test control signal for the port B (TESTB) is LOW, the NAND circuit 11 outputs a signal inverted from the clock signal CLKA for the port A. It should be noticed that, with the NAND circuit 11, an input of the test control signal for the port B (TESTB) is LOW active. The inverting buffer 12 outputs an internal clock signal (A) ICLA which is in phase with the clock signal CLKA. When the test control signal for the port B (TESTB) is HIGH, the output of the NAND circuit 11 is fixed at HIGH, without regard to the value of the clock signal CLKA, in which the clock signal CLKA is masked. The internal clock ICLA from the inverting buffer 12 is fixed at LOW.

The circuit also includes a two-input NAND circuit 13 which has first and second inputs connected to a clock terminal (B) to which a clock signal CLKB is supplied, and a terminal for TEST for the port A (TESTA), respectively, and an inverting buffer 14 that receives an output of the NAND circuit 13. The inverting buffer 14 outputs an internal clock ICLB.

The operation of this circuit portion is now described. When a test control signal for the port A (TESTA) is LOW, the NAND circuit 13 outputs a signal inverted from the clock signal CLKB for the port B. It should be noticed that, with the NAND circuit 13, an input of the test control signal for the port A (TESTA) is LOW active. The inverting buffer 14 outputs an internal clock signal (B) ICLB which is in phase with the clock signal CLKB. When the test control signal for the port A (TESTA) is HIGH, the output of the NAND circuit 13 is fixed at HIGH, without regard to the value of the clock signal CLKB, in which clock signal CLKB is masked. The internal clock ICLB from the inverting buffer 14 is fixed at LOW.

The circuit also includes, as a circuit for controlling the driving of a word line WLA for the port A, a two-input NAND circuit 15, a CMOS transfer gate 17 and an NMOS transistor 18. The two-input NAND circuit receives XKA and XEA which are address selection signals (A) for the port A. The CMOS transfer gate is composed by a PMOS transistor having a gate for receiving an output of the NAND circuit 15, and an NMOS transistor having a gate for receiving an output of the NAND circuit 15 as inverted by an inverter 16. The NMOS transistor 18 has a drain connected to an output of the CMOS transfer gate 17, while having a source connected to the power supply terminal VSS and having a gate connected to an output of the NAND circuit 15. The circuit also includes a first variable delay circuit (Delay Box1) 30 that receives an output of the CMOS transfer gate 17, and a second variable delay circuit (Delay Box2) 31 that receives an output of a second CMOS transfer gate 24 as later described. The circuit further includes a two-input AND circuit 19, a two-input NOR circuit 20, and an inverting word driver 21. The two-input AND circuit 19 receives, as inputs, the test control signal for the port B (TESTB) and an output of the second variable delay circuit (Delay Box2) 31. The two-input NOR circuit 20 receives, as inputs, an output of the first variable delay circuit (Delay Box1) 30 and an output of the AND circuit 19, and the inverting word driver 21 receives an output of the NOR circuit 20. Meanwhile, XKA and XEA are address selection signals (A) that select word line WLA of port A and are outputs of a main pre-decoder (not shown) and a sub pre-decoder (not shown) of an X-address decoder (row-address decoder) for port A, respectively.

The operation of this circuit portion is now described. When both XKA and XEA are HIGH, an output of the NAND circuit 15 becomes LOW to turn on the CMOS transfer gate 17 to transfer and output the input internal clock signal ICLA. If at least one of XKA and XEA is LOW, that is, if the address of the port A of the cell is non-selected, the output of the NAND circuit 15 goes HIGH to turn the CMOS transfer gate 17 off and to turn the NMOS transistor 18 on. The output of the CMOS transfer gate 17 goes LOW.

If the test control signal for the port B (TESTB) is LOW, the output of the AND circuit 19 goes LOW. The NOR circuit 20 supplies to the inverting word driver 21 a signal inverted from an output of the CMOS transfer gate 17 delayed by the first variable delay circuit (Delay Box1) 30.

If the test control signal for the port B (TESTB) is HIGH, with ICLA then being fixed at LOW, the NOR circuit 20 supplies to the inverting word driver 21 a signal inverted from an output of the AND circuit 19. The inverting word driver 21 receives a LOW pulse from the NOR circuit 20 (a reverse-phase signal of ICLB delayed by the second variable delay circuit 31) to drive the word line WLA.

The circuit further includes, as a circuit portion for controlling the driving of the word line WLB of the port B, a two-input NAND circuit 22, a CMOS transfer gate 24 and an NMOS transistor 25. The two-input NAND circuit 22 receives XKB and XEB, which are address selection signals for the port B. The CMOS transfer gate 24 is composed by a PMOS transistor having a gate for receiving an output of the NAND circuit 22, and an NMOS transistor having a gate for receiving an output of the NAND circuit 22 inverted by an inverter 23. The NMOS transistor 25 has a drain connected to an output of the CMOS transfer gate 24, while having a source and a gate connected to the power supply terminal VSS and to the output of the NAND circuit 22, respectively. The circuit further includes a third variable delay circuit (Delay Box1) 32 that receives as an input an output of the CMOS transfer gate 24, and a fourth variable delay circuit (Delay Box2) 33 that receives as an input an output of the CMOS transfer gate 17. The circuit further includes a two-input AND circuit 26, a two-input NOR circuit 27 and an inverting word driver 28. The two-input AND circuit 26 receives the test control signal for the port A (TESTA) and an output of the fourth variable delay circuit (Delay Box2) 33, as inputs. The two-input NOR circuit 27 receives an output of the third variable delay circuit (Delay Box1) 32 and an output of the AND circuit 26, as inputs, and the inverting word driver 28 receives an output of the NOR circuit 20. Meanwhile, XKB and XEB are address selection signals (B) that select word line WLB of port B and are outputs of a main pre-decoder (not shown) and a sub pre-decoder (not shown) of an X-address decoder (row-address decoder) for port B, respectively

The operation of this circuit portion is now described. When both XKB and XEB are HIGH, an output of the NAND circuit 22 becomes LOW to turn on the CMOS transfer gate 24 to transfer and output the input internal clock signal ICLB. If at least one of XKB and XEB is LOW, that is, if the address of the port B of the cell is non-selected, the output of the NAND circuit 22 goes HIGH to turn off the CMOS transfer gate 24 to turn on the NMOS transistor 25. The output of the CMOS transfer gate 24 goes LOW.

If the test control signal for the port A (TESTA) is LOW, the output of the AND circuit 26 goes LOW. The NOR circuit 27 supplies to the inverting word driver 28 a signal inverted from an output of the CMOS transfer gate 24 delayed by the third variable delay circuit 32.

If the test control signal for the port A (TESTA) is HIGH, with ICLB then being fixed at LOW, the NOR circuit 27 supplies to the inverting word driver 21 a signal inverted from an output of the AND circuit 26. The inverting word driver 28 receives a LOW pulse from the NOR circuit 27 (an reverse-phase version of ICLA delayed by the fourth variable delay circuit 33) to drive the word line WLB.

During the normal operation, the test control signals TESTA and TESTB are both set to LOW level. It should be noted that the test control signals are so set during testing as well, except if the ports A and B are subjected to a simultaneous READ test. The activation timing of the word line WLA is controlled via ICLA, CMOS transfer gate 17, first variable delay circuit 30 and NOR circuit 20. The activation timing of the word line WLB is controlled via ICLB, CMOS transfer gate 24, third variable delay circuit 32 and NOR circuit 27, in a manner independent of WLA. Setting both the test control signals TESTA and TESTB is inhibited.

In the present example, the first variable delay circuit 30 and the third variable delay circuit 32 are of the same configuration (Delay Box1). During the normal operation, the delay time of these delay circuits is set to the same delay value.

In the present example, the second variable delay circuit 31 and the fourth variable delay circuit 33 are of the same configuration (Delay Box2).

The delay time of the first to fourth variable delay circuits 30 to 33 is variably set in response to output signals D0 to Dm of a delay decoder 29. The delay decoder 29 receives delay control signals from, for example, external terminals DLY0 to DLYn, and decodes these input signals to supply the output signals D0 to Dm to the first to fourth variable delay circuits 30 to 33. In FIG. 1, n in the terminals DLY0 to DLYn is set to 2 (3-bit signal), and m in the output signals D0 to Dm is set to 6 (7-bit signal), only by way of illustration and not in the way of imposing limitation on the present invention.

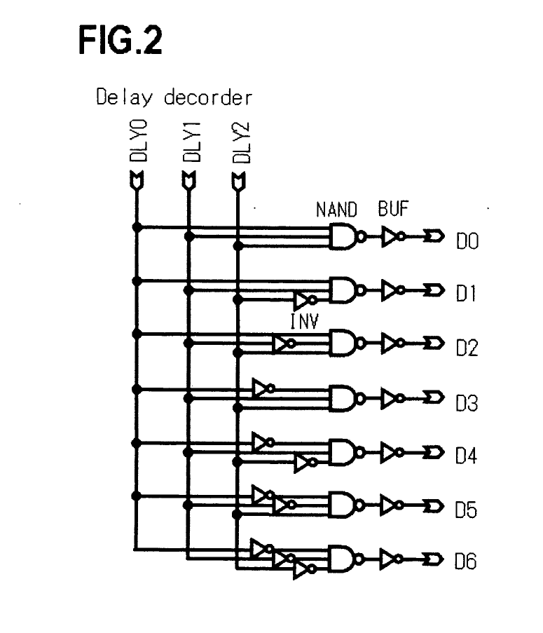

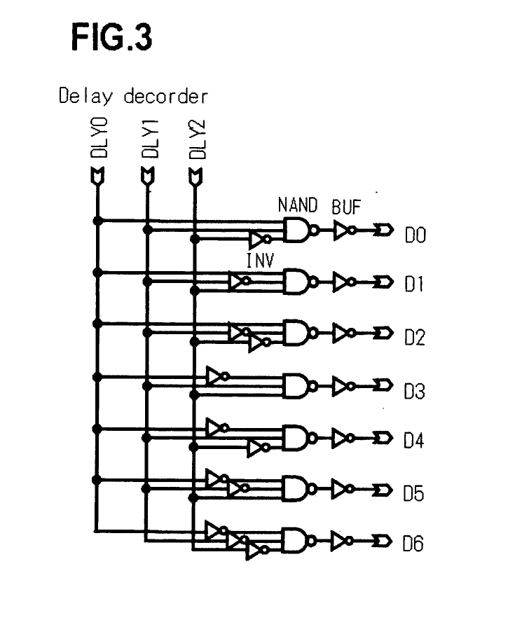

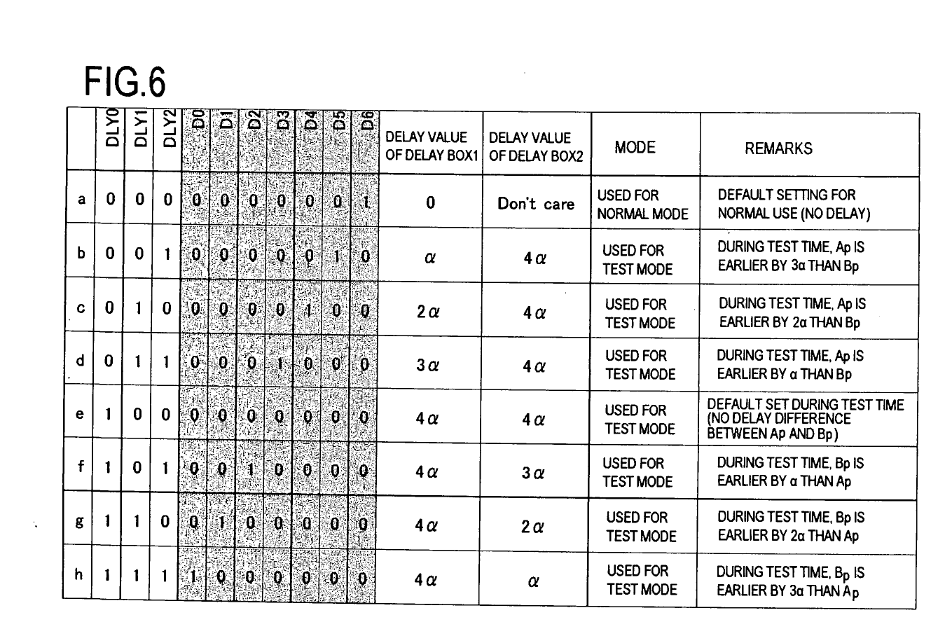

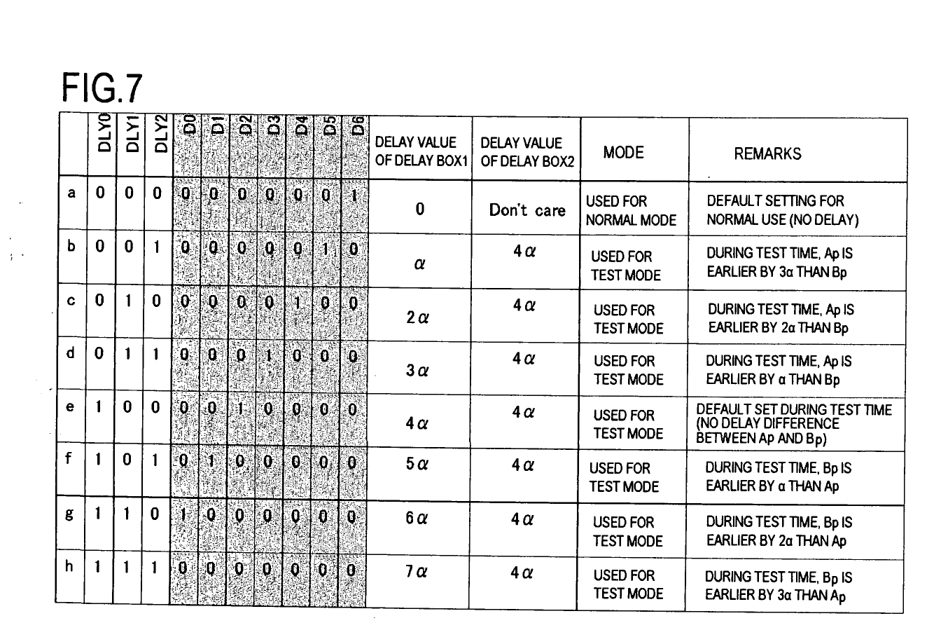

FIGS. 2 and 3 show two illustrative circuit configurations of the delay decoder 29 of FIG. 1. The delay decoder 29, shown in FIG. 2, comprises 3-input NAND circuits, inverter circuits INV and inverting buffers BUF. This circuit configuration implements a circuit of the truth table of DLY0, DLY1 and DLY2 and D0 to D6 of FIG. 6. As an example, D0 is given as D0=NOT (NAND (DLY0, DLY1, DLY2)), such that D0 =1 (logic 1) when (DLY0, DLY1, DLY2) =(1,1,1).

The delay decoder 29, shown in FIG. 3, implements a circuit of the truth table of DLY0, DLY1 and DLY2 and D0 to D6 of FIG. 7. The circuit configuration of FIG. 3 comprises 3-input NAND circuits, inverter circuits INV and inverting buffers BUF. As an example, D0 is given as D0=NOT (NAND (DLY0, DLY1, NOT DLY2)), such that D0 =1 (logic 1) when (DLY0, DLY1, DLY2)=(1,1,0).

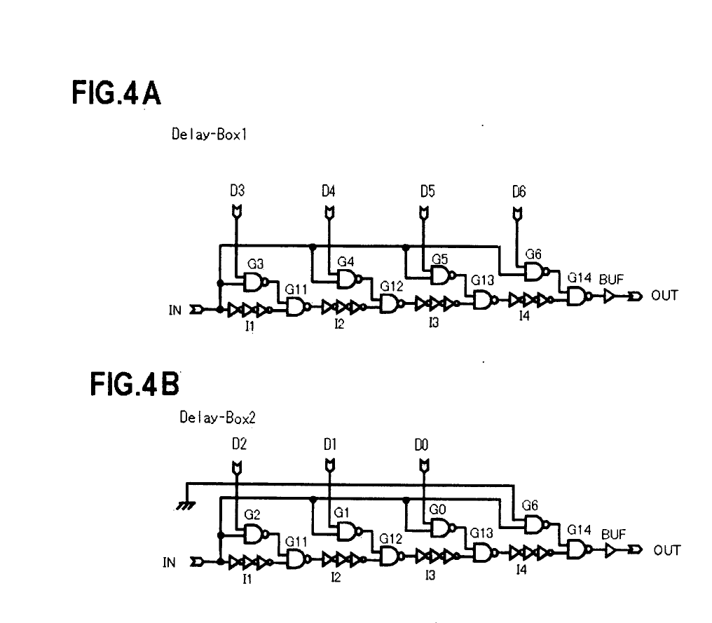

FIG. 4A shows an example of the configuration of the first variable delay circuit (Delay Box1) 30 and the third variable delay circuit (Delay Box1) 32. These are of the same configuration (Delay Box1), and receive upper four bits (D3, D4, D5 and D6) of the 7-bit signal (D0 to D6) from the delay decoder 29, such as to variably set the delay time.

The circuit configuration, shown in FIG. 4A, shows an example of the circuit configuration of the first and third variable delay circuits (Delay Box1) 30 and 32 in case the circuit configuration of FIG. 2 is used as the delay decoder 29 of FIG. 1. The circuit of FIG. 4A implements the relationship between D3 to D6 and the delay value of the Delay Box1 of FIG. 6. With regard to 2-input NAND gates G3 to G6, which respectively receiving the signals D3 to D6 and the input signal from the input terminal IN, the NAND gate associated with one of the signals D3 to D6 which is a HIGH level signal operates as an inverter that delivers an inverted version of the input signal IN. The NAND gate, operating as the inverter, delivers the inverted signal to an associated one of the NAND gates G11 to G14. The signal is then propagated from the NAND gate to subsequent stages of the delay circuits and delivered via a non-inverting buffer BUF to the output terminal OUT. The outputs of those two-input NAND gates, out of the NAND gates G3 to G6, which are supplied with LOW level signals, are fixed at a HIGH level to mask the signal from the input terminal IN.

If, in FIG. 4A, D6 is HIGH, with D3 to D5 being LOW, the gate G6 is open, so that the input signal from the input terminal IN is delivered via gates G6 and G14 so as to be output via buffer BUF to an output terminal OUT. The delay value at this time is set to 0. If, in FIG. 4A, D5 is HIGH, with the other signals being LOW, the gate G5 is open, so that the input signal from IN is delivered via gates G5 and G13, an inverter string 14 and the gate G14 so as to be output via buffer BUF to the output terminal OUT. The propagation delay time since a signal is delivered to the input terminal IN until it is output at the output terminal OUT is a delay value α. This delay value α (unit delay value) corresponds to the sum of delay times in the inverter string 14 made up of three inverter stages and in the NAND gate G14 that receives a HIGH output from NAND gate G6 to operate as an inverter. The delay in each of inverter strings 11 to 14 is of the same value.

In similar manner, if, in FIG. 4A, the signal D4 is HIGH, with the other signals being LOW, the gate G4 is opened. The input signal IN is propagated via gate G12, inverter string (cascade connected inverters) 13, gate G13, inverter string 14, gate G14 and buffer BUF to the output terminal OUT with a delay value of 2α corresponding to the sum of the delay value α of the inverter string 13 and the gate G13 and the delay value α of the inverter string 14 and the gate G14. If the signal D3 is HIGH, with the other signals being LOW, the gate G3 is opened. In this case, the input signal from the input terminal IN is propagated via gate G11, inverter string 12, gate G12, inverter string 13, gate G13, inverter string 14, gate G14 and buffer BUF to the output terminal OUT with a delay value of 3α corresponding to the sum of the delay value α of the inverter string 12 and the gate G12, delay value α of the inverter string 13 and the gate G13 and the delay value α of the inverter string 14 and the gate G14. If the signals D3 to D6 are LOW, the gates G3 to G6 are closed. The input signal from the input terminal IN then is propagated via inverter string 11, gate G11, inverter string 12, gate G12, inverter string 13, gate G13, inverter string 14, gate G14 and buffer BUF to the output terminal OUT with a delay value of 4α corresponding to the sum of the delay value α of the inverter string 11 and the gate G11, delay value α of the inverter string 12 and the gate G12, delay value α of the inverter string 13 and the gate G13 and the delay value α of the inverter string 14 and the gate G14.

FIG. 4B shows an example of the circuit configuration of the second and fourth variable delay circuits in case of using the circuit configuration of FIG. 2 as the delay decoder 29 of FIG. 1. The circuit of FIG. 4B implements the relationship between D0, D1 and D2 of FIG. 6 and the delay value of the Delay Box2. In the circuit of FIG. 4B, the GND level is supplied to the NAND gate G6, its output being thus fixed at HIGH. If D0, D1 and D2 are all LOW, the outputs of the NAND gates G2, G1 and G0 are fixed at HIGH. The input signal from IN is delayed by a delay value 4α of the four stages of the inverter strings and the NAND gates and is output via buffer BUF to the output terminal OUT. If D2 is HIGH, the gate G2 is opened, and hence the input signal from IN is output via gate G2, gate G11, inverter string G12, gate G12, inverter string 13, gate G13, inverter string G14, gate G14 and buffer BUF to the output terminal OUT with a delay value equal to 3α. If D1 is HIGH, the gate G1 is opened, and hence the input signal from IN is output via gate G12, inverter string 13, gate G13, inverter string 14, gate G14 and buffer BUF to the output terminal OUT with a delay value equal to 2α. If D0 is HIGH, the gate G0 is opened, so that the input signal from IN is output via gate G0, gate 13, inverter string 14 and gate G14, with a delay value equal to α.

In case the delay value of the variable delay circuit (Delay Box1) of FIG. 4A is equal to that of the variable delay circuit (Delay Box2) of FIG. 4B, the difference between the port A word line activation timing and the port B word line activation timing is zero, there being no time delay.

It should be noticed that the delay time of the buffer in the variable delay circuit (Delay Box1) of FIG. 4A and the delay time of the buffer in the variable delay circuit (Delay Box2) of FIG. 4B are not taken into account in terms of the delay value α in FIG. 6. The reason is that, in the configuration of FIG. 1, the time difference between the delay of the variable delay circuit (Delay Box1) and that of the variable delay circuit (Delay Box2) is canceled out in the activation timings of the respective word lines WLA and WLB of the ports A and B.

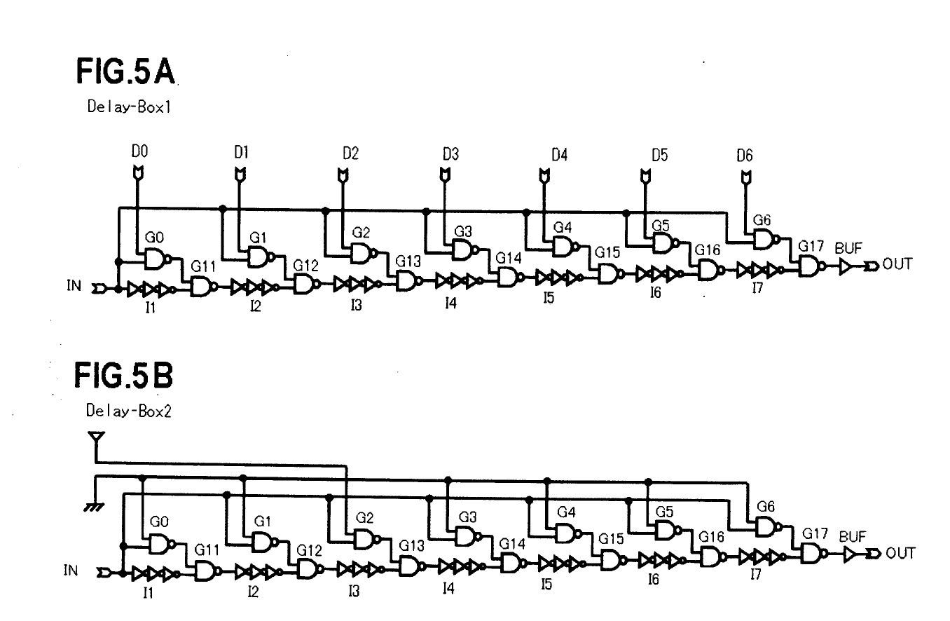

In the present example, the delay value in case the signal D6 is HIGH, with the other signals being LOW, in FIG. 4A, and the route of IN→gate G6→gate G14→) buffer BUFF→OUT has been selected, is set to 0, for convenience in explanation. However, it is of course possible to take the propagation delay time (typical value) of the gates G6, G14 and the buffer BUF into account in order to conduct a marginal test. The same holds for the configuration of FIG. 5 as well.

FIG. 5A is a diagram showing a circuit configuration of the first and third variable delay circuits (Delay Box1) 30, 32 in case of using the circuit configuration of FIG. 3 as the delay decoder 29 of FIG. 1. The circuit shown in FIG. 5A implements the relationship between the signals D0 to D6 and the variable delay circuits (Delay Box1) shown in FIG. 7. Out of the 2-input NAND gates G0 to G6, receiving the signals D0 to D6 and the signal from the -terminal IN, the NAND gate, associated with the HIGH level signal, out of the signals D0 to D6, outputs an inverted version of the input signal. This inverted signal is received by an associated one of the NAND gates G11 to G17, from which it is propagated via succeeding delay circuit(s) and a non-inverting buffer BUF to the output terminal OUT. The outputs of those of the 2-input NAND gates G0 to G6, receiving the LOW level signals, are fixed at a HIGH level to mask the signal from terminal IN.

If, in FIG. 5A, D6 is HIGH, with the other signals being LOW, the delay value is zero.

If D5 is HIGH, with the other signals being LOW, the delay value is α.

If D4 is HIGH, with the other signals being LOW, the delay value is 2α.

If D3 is HIGH, with the other signals being LOW, the delay value is 3α.

If D2 is HIGH, with the other signals being LOW, the delay value is 4α.

If D1 is HIGH, with the other signals being LOW, the delay value is 5α.

If D0 is HIGH, with the other signals being LOW, the delay value is 6α.

If D0 to D6 are all LOW, the delay value is 7α.

In the circuit of FIG. 5B, the GND level is supplied to each of the NAND gates G0, G1, G4, G5 and G6, and hence the outputs thereof are fixed at HIGH. The power supply level and the input signal are supplied to the NAND gate G2. Hence, the gate G12 is opened, so that the input signal is propagated via NAND gate G2, NAND gate G13, inverter string 14, NAND gate G14, inverter string 15, NAND gate G15, inverter string 16, NAND gate G16, inverter string 17 and the NAND gate G17, with the delay value being 4α for all time.

FIG. 6 is a diagram for illustrating the operation in case the configuration of FIG. 2 is used as the delay decoder of FIG. 1, the configuration of FIG. 4A is used as the first and third variable delay circuits 30 and 32 of FIG. 1 and the configuration of FIG. 4B is used as the second and fourth variable delay circuits 31 and 33 of FIG. 1.

For (a), the mode is the normal mode, with TESTA and TESTB both being LOW. The delay value of the first and third variable delay circuits (Delay Box1) 30 and 32 is 0. The outputs of the second and fourth variable delay circuits (Delay Box2) 31 and 33 are not used, and hence the delay is ‘Don't care’. It is noted that, for the normal mode, the AND circuits 19 and 26 are fixed at the LOW level.

For (b), the mode is the TEST mode. The delay value of the first and third variable delay circuits (Delay Box1) 30 and 32 is α and that of the second and fourth variable delay circuits (Delay Box2) 31 and 33 is 4α. The word line of the port A is activated earlier by 3α than the word line of the port B.

For (c) and (d), the mode is the TEST mode. The delay values of the first and third variable delay circuits (Delay Box1) 30 and 32 are 2α and 3α, respectively, while that of the second and fourth variable delay circuits (Delay Box2) 31 and 33 is 4α. Hence, the word line of the port A is activated earlier by 2α and α than the word line of the port B.

For (e), the mode is the TEST mode. The delay value of the first and third variable delay circuits (Delay Box1) 30 and 32 is 4α, while the delay value of the second and fourth variable delay circuits (Delay Box2) 31 and 33 is 4α. The word line of the port A is activated at the same time as the word line of the port B (default setting for TEST).

For (f), (g) and (h), the mode is the TEST mode. The delay value of the first and third variable delay circuits (Delay Box1) 30 and 32 is 4α, while those of the second and fourth variable delay circuits (Delay Box2) 31 and 33 is 3α, 2α and α. Hence, the word line of the port B is activated earlier by 3α, 2α and α than the word line of the port A.

FIG. 7 is a diagram for illustrating the operation in case the configuration of FIG. 3 is used as the delay decoder 29 of FIG. 1, the configuration of FIG. 5A is used as the first and third variable delay circuits 30 and 32 of FIG. 1 and the configuration of FIG. 5B is used as the second and fourth variable delay circuits 31 and 33 of FIG. 1.

For (a), the mode is the normal mode, with TESTA and TESTB both being LOW. The delay value of the first and third variable delay circuits (Delay Box1) 30 and 32 is 0. The outputs of the second and fourth variable delay circuits (Delay Box2) 31 and 33 are not used, and hence the delay is ‘Don't care’. It is noted that, for the normal mode, the AND circuits 19, 26 are fixed at the LOW level.

For (b), the mode is the TEST mode. The delay value of the first and third variable delay circuits (Delay Box1) 30 and 32 is α, while that of the second and fourth variable delay circuits (Delay Box2) 31 and 33 is 4α. The word line of the port A is activated earlier by 3α than the word line of the port B.

For (c) and (d), the mode is the TEST mode. The delay values of the first and third variable delay circuits (Delay Box1) 30 and 32 are 2α and 3α, respectively, while that of the second and fourth variable delay circuits (Delay Box2) 31 and 33 is 4α. Hence, the word line of the port A is activated earlier by 2α and α than the word line of the port B.

For (e), the mode is the TEST mode. The delay value of the first and third variable delay circuits (Delay Box1) 30 and 32 is 4α, while that of the second and fourth variable delay circuits (Delay Box2) 31 and 33 is 4α. The word line of the port A is activated at the same time as the word line of the port B (default setting for TEST).

For (f), (g) and (e), the mode is the TEST mode. The delay value of the first and third variable delay circuits (Delay Box1) 30 and 32 is 5α, 6α and 7α, while that of the second and fourth variable delay circuits (Delay Box2) 31 and 33 is 4α. Hence, the word line of the port A is activated earlier by 3α, 2α and α than the word line of the port B.

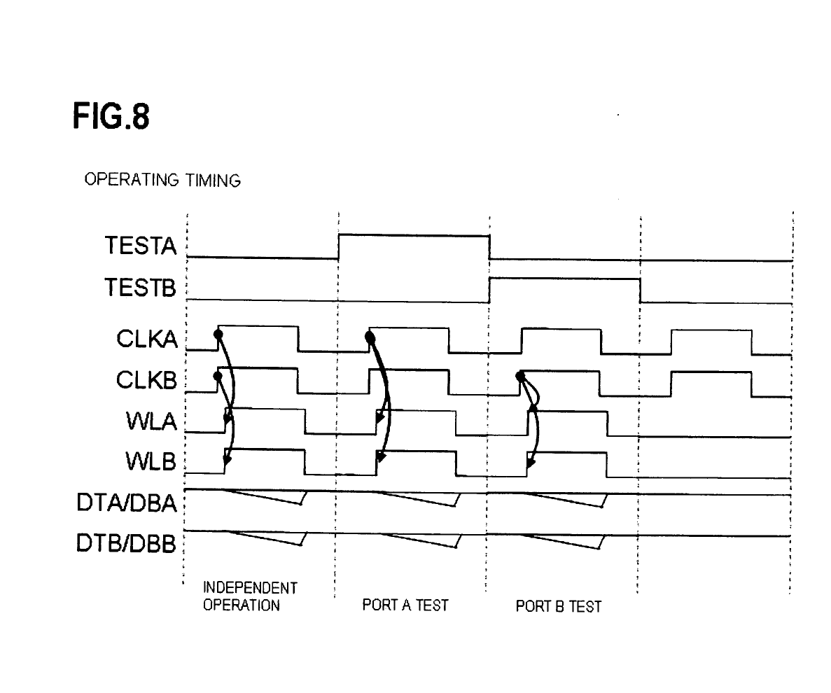

FIG. 8 is a diagram for illustrating the timing of the present example shown in FIG. 1. The operation of the circuit of FIG. 1 is now described with reference to FIG. 8

### Independent Operation

When TESTA and TESTB are both LOW, the NAND circuits 11, 13 output signals inverted from CLKA and CLKB, respectively. As ICLA and ICLB, the internal clock signals in phase with CLKA and CLKB are output. See the ‘independent operation’ of FIG. 8.

Since the signal TESTB is LOW, the output of the AND circuit 19 is fixed at LOW. When XKA and XEA are HIGH, the NOR circuit 20 outputs an inverted version of ICLA output from the first variable delay circuit 30. The word line (A) WLA of the port A is activated in synchronization with the clock ICLA and hence with CLKA.

Also, since the signal TESTA is LOW, the output of the AND circuit 26 is fixed at LOW. When XKA and XEA are HIGH, the NOR circuit 27 outputs an inverted version of ICLB output from the third variable delay circuit 32. The word line (B) WLB of the port B is activated in synchronization with the clock ICLB and hence with CLKB. That is, the word lines of the ports A and B are controlled independently of each other.

### Port A Test

When TESTA is HIGH and TESTB is LOW, the output of the NAND circuit 13 goes HIGH without regard to the value of the clock terminal CLKB, and hence ICLB is fixed at LOW. See the ‘port A test’ of FIG. 8. The output of the AND circuit 19 is fixed at LOW, so that, when XKA and XEA are HIGH, the NOR circuit 20 outputs an inverted version of ICLA output from the first variable delay circuit 30. The word line (A) WLA of the port A is activated in synchronization with the clock ICLA, and hence with CLKA or a signal delayed from CLKA. On the other hand, ICLB is fixed at LOW. When XKB and XEB are HIGH, the NOR circuit 27 outputs an inverted version of an output signal of the AND circuit 26. When the output ICLA of the fourth variable delay circuit 33 is HIGH, the output of the AND circuit 26, receiving the signal TESTA and the output of the fourth variable delay circuit 33, goes HIGH. The word driver 28 sets the word line WLB to HIGH. That is, the word line WLB is activated simultaneously with WLA, or with a delay from WLA corresponding to design delay values of the fourth variable delay circuit (Delay Box2) 33 and the first variable delay circuit (Delay Box1) 30. Read data are output to the bit line pair DTA/DBA of the port A and to the bit line pair DTB/DBB of the port B. This gives a worst case condition for the simultaneous READ if the delay value of the fourth variable delay circuit (Delay Box2) 33 and the first variable delay circuit (Delay Box1) 30 is set to 4α.

### Port B Test

When TESTB is HIGH and TESTA is LOW, the output of the NAND circuit 11 becomes HIGH without regard to the value of the clock terminal CLKA, and hence ICLA is fixed at LOW. See the ‘port B test’ of FIG. 8. The output of the AND circuit 26 is fixed at LOW, so that, when XKB and XEB are HIGH, the NOR circuit 27 outputs an inverted version of ICLB output from the third variable delay circuit 32. The word line (A) WLB of the port B is activated in synchronization with the clock ICLB, and hence with CLKB or a signal delayed from CLKB. On the other hand, ICLA is fixed at LOW. When XKA and XEA are HIGH, the NOR circuit 20 outputs an inverted version of an output signal of the AND circuit 19. When the output ICLB of the second variable delay circuit 31 is HIGH, the AND circuit 19 goes HIGH. The word driver 21 sets the word line WLA to HIGH. That is, WLA is activated simultaneously with WLB, or with a delay from WLB corresponding to design delay values of the second variable delay circuit (Delay Box2) 31 and the third variable delay circuit (Delay Box2) 32. Read data are output to the bit line pair DTB/DBB of the port B and to the bit line pair DTA/DBA of the port A. This gives a worst case condition for the simultaneous READ if the delay value of the second variable delay circuit (Delay Box2) 31 and that of the third variable delay circuit (Delay Box1) 32 are set to 4α.

Thus, in the present example, a logic of a test control signal of one of the ports and the word line activation signal of the other port is added in the activation control of the word lines on the same row. If the test control signal of the one port is enabled, the word line of the other port is driven with a signal transition timing which is the same as that of the word line of the one port or with a signal transition timing which has a preset lag and lead time with respect to those of the word line of the one port. In order not to obstruct the word line driving of the other port, logical operation of the test control signal of the one port and the clock signal of the other port entered from outside are performed, in such a manner that, when the test control signal of the one port is enabled (HIGH), the internal clock of the other port is not output.

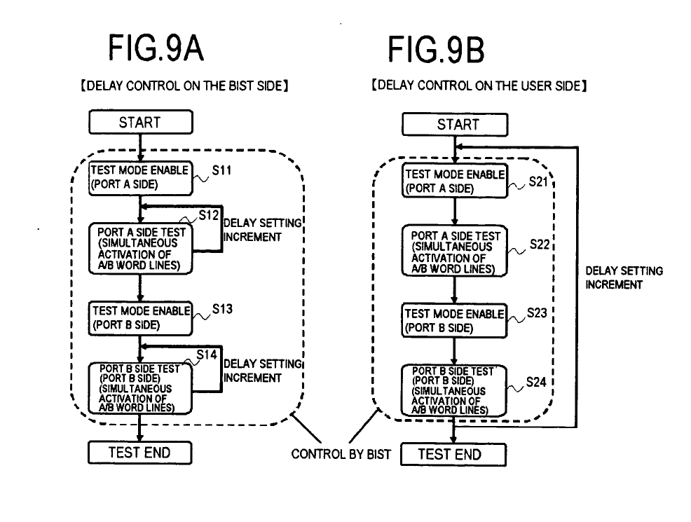

FIGS. 9A and 9B are flowcharts for illustrating an example of a testing method for the above-described example of the semiconductor device. FIG. 9A shows an example of controlling the delay time of the variable delay circuits (Delay Box1 and Delay Box2) on the BIST side. The TEST mode is enabled and the test control signal TESTA is activated (set to HIGH). The control signal TESTB is set to LOW (step S11). The port A side is tested. The port A word line and the port B word line are activated simultaneously. In simultaneously activating the port A word line and the port B word line, the delay time of the variable delay circuits (Delay Box1 and Delay Box2) is sequentially varied to carry out READ with simultaneous activation of the port A word line and the port B word line (step S12). In setting the delay time, the timing difference between the port A word line and the port B word line may be varied stepwise so that the timing difference will be incremented from −3α through −2α, −α, 0, α, 2αto 3α, for example.

The test control signal TESTB is activated (set to HIGH). The control signal TESTA is set to LOW (step S13). The port A side is tested. The port A word line and the port B word line are activated simultaneously. In simultaneously activating the port A word line and the port B word line, the delay time of the variable delay circuits (Delay Box1 and Delay Box2) is sequentially varied to carry out READ with simultaneous activation of the port A word line and the port B word line (step S14). In setting the delay time, the timing difference between the port A word line and the port B word line may be varied stepwise so that the timing difference will be incremented from −3α through −2α, −α, 0, α, 2α to 3α, for example.

FIG. 9B shows an example in which the delay time of the variable delay circuits (Delay Box1 and Delay Box2) is controlled on the user side (on the user logic side or on the tester side). The TEST mode is enabled and the test control signal TESTA is activated (set to HIGH). The control signal TESTB is set to LOW (step S21). The port A side test is conducted. The port A word line and the port B word line are activated simultaneously (step S22). The test control signal TESTB is activated, that is, set to HIGH. The test control signal TESTA is brought LOW (step S23). The port A side test is conducted. The port A word line and the port B word line are activated simultaneously (step S24). In the present example, in simultaneously activating the port A word line and the port B word line, the delay time of the variable delay circuits (Delay Box1 and Delay Box2) is sequentially varied, each time reversion is made to the step S21, in order to make fine adjustment of the activation timings of the port A word line and the port B word line to effect READ. In setting the delay time, the delay time of the variable delay circuits (Delay Box1 and Delay Box2) is sequentially varied to carry out READ. In setting the delay time, the timing difference between activation of the port A word line and that of the port B word line may be varied stepwise so that the timing difference will be incremented from −3α through −2α, −α, 0, α, 2α to 3α, for example.

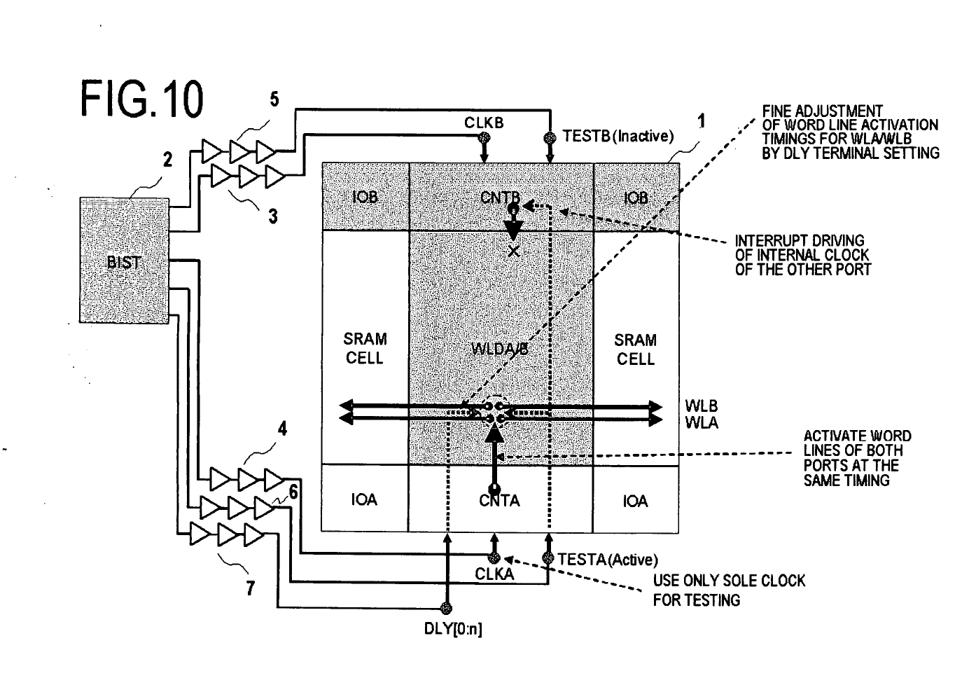

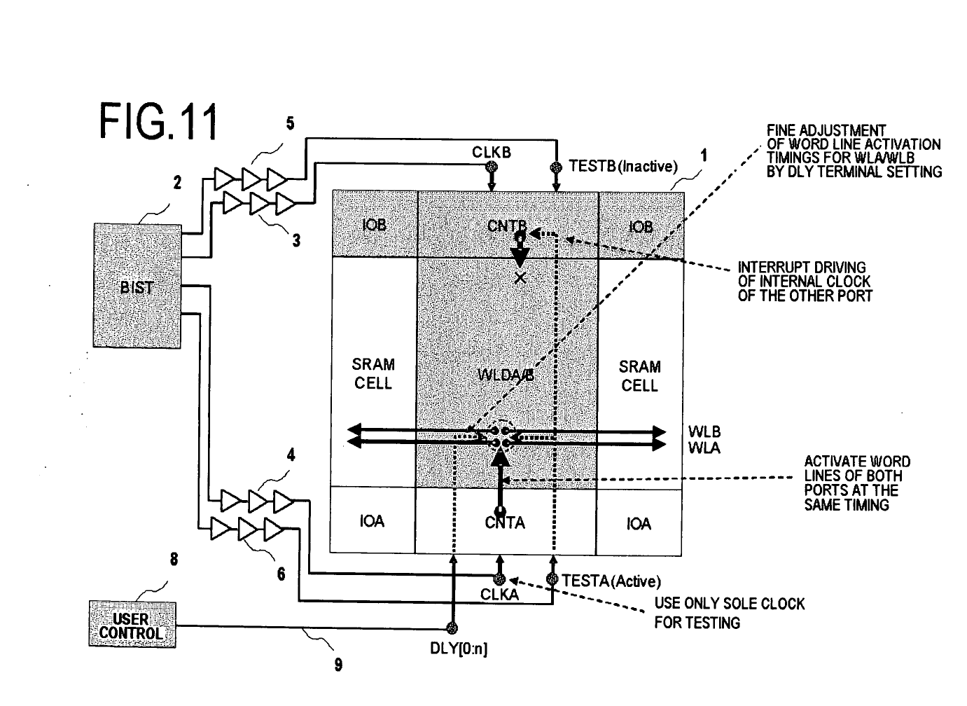

FIG. 10 is a schematic view for illustrating the operation of an example of the present invention. Specifically, FIG. 10 shows an example of controlling the delay time of the variable delay circuits (Delay Box1 and Delay Box2) on the BIST side. The test control signal of the port of interest is activated (enabled) and a clock is delivered to the port of interest. The word line of the port of interest is driven, while the word line of the other port on the same row is driven at the same timing to effect the READ operation of the port of interest. The internal clock signal at the other port is fixed at LOW so that the driving of the word line at the other port will not be obstructed even though the clock is delivered to the other port.

Referring to FIG. 10, the clock signal CLKA and the test control signal TESTA are delivered from the BIST 2 via a clock buffer 4 and a signal buffer 6 to terminals CLKA and TESTA of the port A of the memory circuit 1, respectively. Also, the clock signal CLKB and the test control signal TESTB are delivered from the BIST 2 via a clock buffer 3 and a signal buffer 5 to terminals CLKB and TESTB of the port B of the memory circuit 1, respectively.

If, in the example shown in FIG. 10, the ports A and B of the selected cell are activated at the same timing, the signals TESTA and TESTB are set to HIGH and LOW, respectively. The word line WLA of the port A and the word line WLB of the port B are activated simultaneously, using the clock CLKA for the port A. That is, only a sole clock is used during the testing to interrupt word line driving by the internal clock of the other port B.

The delay control signal from BIST 2 is delivered to DLY terminals, via signal buffer 7, to set the delay time of the variable delay circuits (Delay Box1 and Delay Box2) of FIG. 1. This setting of the delay time enables fine adjustment of the difference in the activation timing of the word lines of the ports A and B, inclusive of the zero activation timing difference.

With the present example, the same clock (the clock from the clock terminal CLKA of the port A) is delivered to the circuit that controls the driving of the word lines WLA and WLB (see FIG. 1). Thus, the word lines WLA and WLB may be activated at the timing indicated in FIG. 13C, without being affected by the skew, if any, of the internal clock from one port to the next, which might be caused by the difference in the physical layout within the memory circuit 1. That is, the word lines of the two ports can be activated simultaneously.

That is, in simultaneous READ of the two ports, the word lines of the two ports A and B are driven by the same clock. Hence, the clock skew of the internal clocks between the ports A and B, ascribable to device-based variations between BIST 2 and the memory circuit 1, is not of a problem. Further, the clock skew of the internal clock from one port to the next, ascribable to the difference in the physical layout in the memory circuit 1, is also not of a problem. Additionally, fine adjustment of the activation timings of the word lines WLA and WLB of the ports A and B may be made by setting from the DLY terminals, as the word lines of the ports A and B are driven by the same clock.

FIG. 11 is a schematic view for illustrating the operation of a modification of the present invention. Specifically, FIG. 11 shows an example of controlling the delay time of the variable delay circuits (Delay Box1 and Delay Box2) of FIG. 1 by a tester (user).

Referring to FIG. 11, the clock signal CLKA and the test control signal TESTA are supplied from BIST 2 via the clock buffer 4 and the signal buffer 6 to the terminals CLKA and TESTA of the port A of the memory circuit 1, whilst the clock signal CLKB and the test control signal TESTB are supplied from BIST 2 via the clock buffer 3 and the signal buffer 5 to the terminals CLKB and TESTB of the other port B of the memory circuit 1.

If, in the example shown in FIG. 11, the ports A and B of a selected cell are activated at the same timing, the signals TESTA and TESTB are set to HIGH and LOW, respectively. The word line A of the port A and the word B of the port B are activated simultaneously, using the clock CLKA for the port A. It should be noticed that, during the test, the sole clock is used, while the word line driving of the other port B by the internal clock is interrupted.

A delay control signal 9 from a user control, such as a tester 8, is delivered to DLY terminals to set the delay time of the variable delay circuits (Delay Box1 and Delay Box2) of FIG. 1. By this setting of the delay time, it is possible to make fine adjustment of the difference in the activation timing of the word lines of the ports A and B. The word lines WLA and WLB may be activated at the timing indicated in FIG. 13C, without being affected by the skew, if any, of the internal clock which might be caused from one port to the next by the difference in the physical layout within the memory circuit 1. That is, the word lines of the two ports can be activated simultaneously.

FIG. 16 is a block diagram illustrating the configuration according to an example of the present invention. Referring to FIG. 16, a memory circuit includes a delay decoder 29, an internal clock B output circuit 42, an internal clock A output circuit 44, an X address decoder 30, a word driver control circuit 46 and a word driver 48. Meanwhile, in FIG. 16, the word driver control circuit 46 and the word driver 48 may be combined to form one block.

A BITS (Built In Self Test) circuit 2 provides respective clock signals for ports A and B via a clock buffer 3 and a clock buffer 4 to the memory circuit 1. The BITS circuit 2 also provides respective test signals for ports A and B via a signal buffer 5 and a signal buffer 6 to the memory circuit 1. The BITS circuit 2 may also provide a delay control signal to the delay decoder 29 which provides decoded output signals D0-Dm to variable delay circuits 30-33 (not shown) provided in the word driver control circuit 46.

The internal clock A output circuit 44 is supplied with a clock signal CLKA for a port A and a test signal TESTB for a port B and outputs an internal clock ICLKA for a port A.

The internal clock B output circuit 42 is supplied with a clock signal CLKB for a port B and a test signal TESTA for a port A and outputs an internal clock ICLKB for a port B.

The address decoder 30 is supplied with an X address out of an address output from the BITS circuit 2 and outputs address selection signals XKA and XEA for port A, and address selection signals XKB and XEB for port B. A Y address out of an address output from the BITS circuit 2 is supplied to a column decoder not shown.

The word driver control circuit 46 is supplied with the internal clock signals ICLKA and ICLKB, the test control signals TESTA and TESTB, the address selection signals XKA and XEA, and the address selection signals XKB and XEB and outputs a signal controlling the activation of the selected word line.

The word driver 48 drives a word line WLA for a port A and a word line WLB for a port B for a selected cell in a memory cell array 32, based upon output signals from the word driver control circuit 46, respectively.

In FIG. 16, the internal clock A output circuit 44 is composed by for example the NAND 11 and inverter 12 in FIG. 1. The internal clock B output circuit 42 is composed by for example the NAND 13 and inverter 14 in FIG. 1. The word driver control circuit 46 is composed by for example the NAND 15, inverter 16, CMOS transfer gate 17, NMOS transistor 18, AND 19, NOR 20, NAND 22, inverter 23, CMOS transfer gate 24, NMOS transistor 25, AND 26, NOR 27, and variable delay circuits 30-33, in FIG. 1. The word driver 48 includes for example inverting drivers (inverters) 21 and 28 which drive the word lines WLA and WLB, respectively.

With the present example, described above, the following operation and meritorious effect may be derived.

Pre-shipment testing of memory circuits may be conducted under the condition of the severest operational margin, thereby decreasing the rate of post-shipment rejects.

For pre-shipment test such as production testing, proper testing standards can be set, thereby improving the yield.

By entering a delay control signal for controlling the activation of the word lines of the plurality of ports, it is possible to make fine adjustment of the activation timings of the word line of a given port and that of the other port. That is, by setting from the DLY terminals, the timing difference between the activation timing of the word line of the port A and that of the word line of the port B, inclusive of zero timing difference, may be adjusted finely, as the word lines of the ports A and B are being driven by the same clock, it is possible to improve accuracy in testing, such as in timing margin testing.

In the above-described examples, a clock synchronized static memory circuit including a dual-port SRAM cell explained with reference to FIG. 12, is taken as an example. In this static memory circuit, the ports A and B are used as read/write I/O ports, and simultaneous READ of the ports A and B is possible. However, the static memory circuit may be so designed and constructed that the ports A and B are used as a write-only port and as a readout-only port, respectively, or vice versa. Also, the present invention is not limited to the dual-port configuration of the ports A and B, and may similarly be applied to a cell with more than two ports.

It is sufficient that the delay values of the variable delay circuits (Delay Box1 and Delay Box2) can be variably set based on a control signal. That is, the configurations shown in FIGS. 4 and 5 are merely illustrative and are not to be interpreted in the restricting way.

The disclosures of the above-listed Patent Publications are to be incorporated herein by reference. The examples or examples can be changed or adjusted within the framework of the entire disclosures of the present invention, inclusive of the claims, based on the fundamental technical concept of the invention. Various combinations or selections of disclosed elements are also possible within the framework of the claims of the present invention. That is, the present invention comprises various changes or corrections that may be made by those skilled in the art based on the entire disclosures, inclusive of claims, and on its technical concept.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor memory device comprising:
a memory cell connected to a plurality of word lines corresponding respectively to a plurality of ports; and
a control circuit that controls to activate each of the plurality of word lines corresponding respectively to the plurality of ports, responsive to each of a plurality of timing signals corresponding respectively to the plurality of ports,
said control circuit activating the plurality of word lines responsive to an associated one of the plurality of timing signals in accordance with a plurality of test control signals supplied thereto, and variably controlling respective activation timings of the plurality of word lines which are activated responsive to the associated one timing signal.

2. The semiconductor memory device according to claim 1, wherein
a plurality of the test control signals are provided associated respectively with a plurality of the timing signals which are for controlling the activation timings of word lines of the plurality of ports;
wherein with regard to the memory cell with the plurality of ports thereof being selected, when one of the plurality of test control signals respectively associated with the plurality of ports selected, is in an activated state, and the remaining test control signals are in a non-activated state, p1 said control circuit exercises control so as to mask the timing signals associated with the non-activated test control signals, and to activate the word lines of the plurality of ports selected in response to the sole timing signal associated with the test control signal in the activated state,
said control circuit, based on a delay control signal supplied thereto, variably controlling the activation timing of the word lines of the plurality of ports activated in response to said one timing signal.

3. The semiconductor memory device according to claim 2, wherein, when said test control signals associated with the plurality of ports selected, are all in the non-activated state, said control circuit exercises control so that the word lines of the plurality of ports are activated independently of each other, based on the plurality of timing signals associated with the plurality of test control signals.

4. The semiconductor memory device according to claim 2, wherein said control circuit exercises control so that, in activating the word lines on the same row, when the test control signal associated with one of first and second ports is activated, the word lines of the other of the first and second ports are activated with a timing difference, inclusive of zero timing difference, as set based on said delay control signal, with respect to the activation timing of said word lines of said one port.

5. A semiconductor memory device comprising:
a memory cell connected to respective word lines of at least a first port and a second port:
first and second test control signals associated with first and second clock signals, said first and second test control signals used for controlling activation timings of the word lines of the first and second ports;
a first control circuit that, with regard to a memory cell with the first and second ports thereof being selected, when the first test control signal is in an activated state and the second test control signal is in a non-activated state, exercises control to mask the second clock signal, and that exercises control to activate the word lines of the first and second ports in response to the first clock signal,
said first control circuit, in activating the word lines of the first and second ports in response to the first clock signal, variably adjusting the activation timing of the word lines of the first and second ports based on a delay control signal received; and
a second control circuit that, with regard to the memory cell with the first and second ports thereof being selected, when the second test control signal is in an activated state and the first test control signal is in a non-activated state, exercises control to mask the first clock signal, and that exercises control to activate the word lines of the first and second ports in response to the second clock signal,
said second control circuit, in activating the word lines of the first and second ports in response to the second clock signal, variably adjusting the activation timing of the word lines of the first and second ports based on the delay control signal.

6. The semiconductor memory device according to claim 5, wherein, when, for a memory cell with the first and second ports thereof being selected, the first and second test control signals are both in a non-activated state, said first and second control circuits exercise control so that the activation of the word lines of the first port and the activation of the word lines of second ports are exercised independently of each other based on the first and second clock signals.

7. The semiconductor memory device according to claim 5, further comprising:
a first circuit that receives the first clock signal and the second test control signal; said first circuit outputting the first clock signal as a first internal clock signal in case the second test control signal is in an inactivated state; said first circuit not transferring the first clock signal and fixing the first internal clock signal in a non-activated state in case the second test control signal is in an activated state;
a second circuit that receives the second clock signal and the first test control signal; said second circuit outputting the second clock signal as a second internal clock signal in case the first control signal is in a non-activated state; said second circuit not transferring the second clock signal and fixing the second internal clock signal in a non-activated state in case the first test control signal is in an activated state;
a first switch that receives the first internal clock signal from the first circuit, said first switch being turned on to transfer and output the first internal clock signal when the address selection signal of the first port indicates a selected state;
a second switch that receives the second internal clock signal from the second circuit, said second switch being turned on to transfer and output the second internal clock signal when the address selection signal of the second port indicates a selected state;
first and third variable delay circuits that receive an output signal from the first switch in common;
second and fourth variable delay circuits that receive an output signal from the second switch in common;
a first logic circuit that receives the second test control signal and a signal which is an output of the second switch delayed by said third variable delay circuit; said first logic circuit outputting a signal in a non-activated state when one or both of inputs are in a non-activated state and outputting a signal in an activated state when both of the inputs are in an activated state;
a second logic circuit that receives an output signal of the first logic circuit and a signal which is an output of said first switch delayed by said first variable delay circuit; said second logic circuit outputting one of inputs when the other input is in a non-activated state;
a first word driver that receives the output signal of said second logic circuit to drive the word lines of the first port;
a third logic circuit that receives the first test control signal and a signal which is the output signal of said first switch delayed by said fourth variable delay circuit; said third logic circuit outputting a signal in a non-activated state if one or both of inputs are in a non-activated state and outputting a signal in an activated state if both inputs are in an activated state;
a fourth logic circuit that receives an output signal of said third logic circuit and a signal which is an output signal of said second switch delayed by said third variable delay circuit; said fourth logic circuit outputting one of inputs if the other input is in a non-activated state; and
a second word driver that receives an output signal of said fourth logic circuit to drive the word line of the second port.

8. The semiconductor memory device according to claim 7, wherein
said first logic circuit and said third logic circuit each comprise an AND gate;
said second logic circuit and said fourth logic circuit each comprise a NOR gate; and
said first word driver and said second word driver each comprise an inverting driver.

9. The semiconductor memory device according to claim 1, wherein the memory cell comprises a static-type cell that includes:
two inverters having inputs and outputs cross-connected at first and second nodes;
first and second access transistors inserted between the first node and bit lines of the first and second ports, respectively, and having control terminals connected to word lines of the first and second ports, respectively; and
third and fourth access transistors inserted between the second node and complementary bit lines of the first and second ports, respectively, and having control terminals connected to word lines of the first and second ports, respectively.

10. The semiconductor memory device according to claim 1, wherein the delay control signal is supplied from a BIST (Built-in Self Test) circuit or from an external terminal of a semiconductor memory device.

11. A testing method of a semiconductor memory device including a memory cell connected to at least a word line of a first port and a word line of a second port, the testing method comprising:
providing first and second test control signals, in association with first and second clock signals used respectively for controlling activation timings of the word lines of the first and second ports;
with regard to a memory cell with the first and second ports thereof being selected, masking the second clock signal if the first test control signal is in an activated state and the second test control signal is in a non-activated state, and activating the word lines of the first and second ports at the same timing or different timings, in accordance with a value as set based on a delay control signal received, in response to the first clock signal, to read cell data from bit lines of the first and second ports; and
masking the first clock signal if the second test control signal is in an activated state and the first test control signal is in a non-activated state, and activating the word lines of the first and second ports at the same timing or different timings, in accordance with a value as set based on a delay control signal, in response to the second clock signal, to read cell data from bit lines of the first and second ports.
